(19) United States
(12) Patent Application Publication
(10) Pub. No.: US 2008/0074151 A1
(43) Pub. Date: Mar. 27, 2008

(54) DUAL-EDGE-TRIGGERED, CLOCK-GATED LOGIC CIRCUIT AND METHOD

(75) Inventor: Min-Su KIM, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/843,780

(22) Filed: Aug. 23, 2007

(30) Foreign Application Priority Data
Sep. 22, 2006 (KR) 10-2006-0092465

(51) Int. Cl. H03K 19/096; H03L 7/24

(52) U.S. Cl. 326/94; 327/144

(57) ABSTRACT

A dual-edge-triggered clock-gated logic circuit includes; a delay clock generator operating to generate first, second, third and fourth delay clock signals in response to a clock signal, and a pulse generator operating to generate a pulse signal in response to the clock signal, the first, third, and fourth delay clock signals, and the control signal. The pulse generator operates to generate the pulse signal at the rising and falling edges of the clock signal.

### CROSS-REFERENCE TO RELATED APPLICATIONS

This U.S. non-provisional patent application claims priority under 35 U.S.C. § 119 of Korean Patent Application No. 10-2006-0092465 filed on Sep. 22, 2006, the subject matter of which is hereby incorporated by reference.

### BACKGROUND OF THE INVENTION

1. Field of the Invention

The present invention relates to clock-gated logic circuits. More particular, the invention relates to a clock-gated, logic circuit generating a pulse signal to trigger a flip-flop circuit on both rising and falling edges of a clock signal and capable of high-frequency operation with relatively low power consumption.

2. Description of the Related Art

Logic circuits generally operate synchronously with a clock signal. Logic circuits are frequently configured to operate with a plurality of flip-flops acting as input/output (I/O) latch circuits. In this manner data I/O operations may be performed synchronously with a defined clock signal.

Recent digital system design trends require high speed operation (i.e., high clock signal frequencies) while minimizing the power consumed by circuits such as flip-flop circuits. As a result, the use of clock-gated logic circuits or clock-gated latch circuits has been proposed. A clock-gated logic circuit receives an externally provided clock signal and generates a corresponding clock signal applied to the flip-flop circuits. The conventional clock-gated logic circuit is designed to generate the corresponding clock signal during an active period defined by a control signal.

In many applications, the flip-flop circuits coupled to the clock-gated logic circuit include a master-slave flip-flop circuit employing two latches and a pulse-based flip-flop circuit.

The master-slave flip-flop circuit includes a master latch and a slave latch. The master latch is synchronized with the clock signal provided by the clock-gated logic circuit, and passes data when the clock signal is logically “low”, but latches data when the clock signal is “high”. In contrast, the slave latch passes data when the clock signal provided by the clock-gated logic circuit is high and latches data when the clock signal is low.

A pulse-based flip-flop circuit includes a pulse generator and a latch. The pulse generator receives a clock signal from the clock-gated logic circuit and generates pulses on the rising edges of the clock signal. The latch synchronously functions as a flip-flop in relation to the pulses provided by the pulse generator.

The master-slave flip-flop circuit employs two latches, but the pulse-based flip-flop circuit employs a single latch. Thus, as the pulse-based flip-flop circuit is smaller than the master-slave flip-flop circuit in area, it consumes relatively less power and reduces the overall delay of signals being transmitted by the circuit. These qualities make the pulse-based flip-flop circuit an excellent choice for use in systems requiring high operating speed.

The conventional clock-gated logic circuit generates a clock signal at either the rising or falling edge of a single externally provided clock signal during an active period defined by an enabling signal, and thereafter transfers the generated clock signal to its constituent flip-flop circuit. That is, the clock-gated logic circuit functions to gate the externally provided clock signal.

During operations of these circuits, parasitic capacitances are inevitably generated at input/output terminals and internal sides of the clock-gated logic circuit, and an input terminal and internal sides of the flip-flop circuit. Such parasitic capacitances are repeatedly charged and discharged at rising and falling edges of each clock signal cycle. In other words, two charge switching operations are effectively performed during each clock signal cycle in relation to the parasitic capacitances. Further, since the conventional clock-gated logic circuit operates at either the rising or falling edge of the clock signal, power consumption due to charge switching occurs with every cycle. For example, when the clock-gated logic circuit is operating on only the rising edge of the clock signal, power consumption nonetheless occurs due to discharge of the parasitic capacitances on the falling edge of the clock signal because the clock-gated logic circuit does not operate on the falling edge. Moreover, the pulse generator of the pulse-based flip-flop circuit generates pulses only at rising edges of the clock signal.

### SUMMARY OF THE INVENTION

Embodiments of the invention are directed to a dual-edge triggered, clock-gated logic circuit capable of operation at high frequency with relatively low power consumption. Embodiments of the invention are also directed to a method of operating this type of circuit.

In one embodiment, the invention provides a dual-edge-triggered clock-gated logic circuit comprising; a delay clock generator operating to generate first, second, third and fourth delay clock signals in response to a clock signal, and a pulse generator operating to generate a pulse signal in response to the clock signal, the first, the third, and the fourth delay clock signals, and the control signal, wherein the pulse generator operates to generate the pulse signal at the rising and falling edges of the clock signal.

In another embodiment, the invention provides a dual-edge-triggered clock-gated logic circuit comprising; a delay clock generator operating to generate first, second, third and fourth delay clock signals in response to a clock signal, and a pulse generator operating to generate a pulse signal in response to the clock signal, the first, third, and fourth delay clock signals, and the control signal, wherein the delay clock generator comprises; first, second, third, and fourth delay clock generators operating to respectively generate the first delay clock signal, the second delay clock signal, the third delay clock signal, and the fourth delay clock signal, wherein the pulse generator comprises; a first transistor connected between a power source voltage and a first node and operating in response to a ground voltage, a second transistor connected between the first node and a second node and operating in response to the control signal, third and fourth transistors serially connected between the second node and the ground voltage and operating in response to the clock signal and the third delay clock signal, fifth and sixth transistors serially connected between the second node and the ground voltage and operating in response to the first delay clock signal and the fourth delay clock signal, and an inverter outputting the pulse signal in response to a voltage apparent at the first node, wherein the pulse generator operates to generate the pulse signal at the rising and falling edges of the clock signal during an active period defined by the control signal.

In another embodiment, the invention provides a method for operating a dual-edge-triggered clock-gated logic circuit, comprising; generating a first delay clock signal by inverting and delaying a clock signal by a first delay period, generating a second delay clock signal by inverting and delaying the first delay clock signal by a second delay period, generating a third delay clock signal by inverting and delaying the second delay clock signal, generating a fourth delay clock signal by inverting and delaying the third delay clock signal, and generating a pulse signal in response to the clock signal, the first, third, and fourth delay clock signals, and a control signal, wherein the pulse signal is generated at the rising and falling edges of the clock signal during an active period defined by the control signal.

### BRIEF DESCRIPTION OF THE DRAWINGS

FIG. 1 is a block diagram of a dual-edge-triggered clock-gated logic circuit according to a preferred embodiment of the present invention;

FIG. 2 is a circuit diagram of the pulse generator shown in FIG. 1;

FIG. 3 is a circuit diagram of the delay clock generator shown in FIG. 1;

FIG. 4 is an operational timing diagram of the dual-edge-triggered clock-gated logic circuit shown in FIG. 1; and

FIG. 5 is a block diagram of a logic circuit synchronized with the dual-edge-triggered clock-gated logic circuit in accordance with a preferred embodiment of the present invention.

### DESCRIPTION OF EMBODIMENTS

Embodiments of the invention will be described with reference to the accompanying drawings. The present invention may, however, be embodied in different forms and should not be constructed as being limited to only the illustrated embodiments. Rather, the embodiments are presented as teaching examples. Throughout the drawings and the written description, like reference numerals refer to like or similar elements.

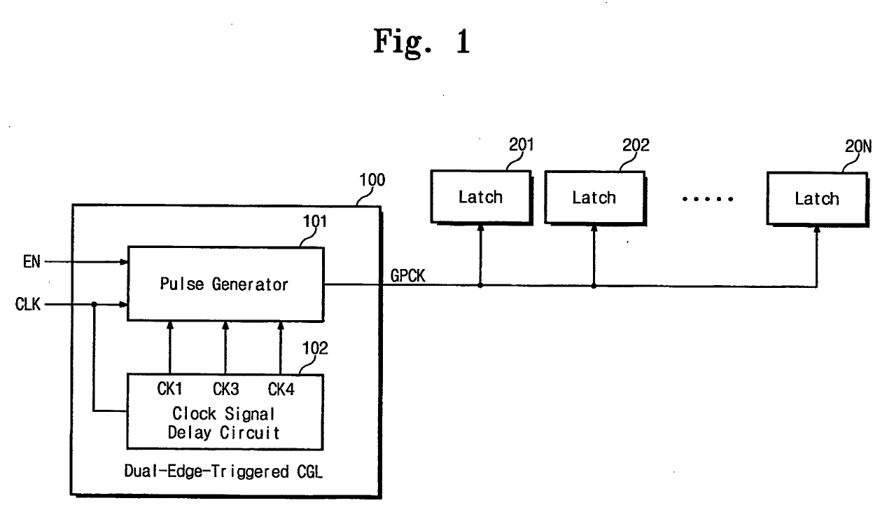

FIG. 1 is a block diagram of a dual-edge triggered, clock-gated logic circuit according to an embodiment of the invention.

Referring to FIG. 1, the dual-edge triggered, clock-gated logic (hereinafter, referred to as ‘dual-edge-triggered CGL’) circuit 100 generally comprises a pulse generator 101 and a delay clock generator 102.

The pulse generator 101 of the dual-edge-triggered CGL circuit 100 receives a control signal (i.e., enabling signal) EN from an external controller (not shown) and a single clock signal CLK from an external source such as a clock generator (not shown).

The delay clock generator 102 receives the clock signal CLK from the clock generator and generates first through fourth delay clock signals CK1, CK2, CK3, and CK4 having predetermined respective delays in response to the clock signal CLK. The delay clock generator 102 provides the first, third, and fourth delay clock signals CK1, CK3, and CK4, among the first through fourth delay clock signals CK1˜CK4 to the pulse generator 101.

The pulse generator 101 receives the single clock signal CLK, and the first, third, and fourth delay clock signals CK1, CK3, and CK4, and generates a pulse signal GPCK at the rising and falling edges of the clock signal CLK during an active period defined by the control signal EN in response to the first, third, and fourth delay clock signals CK1, CK3, and CK4.

Referring to FIG. 5, a logic circuit 200 includes pluralities of latches, 201 to 20N and receives the pulse signal GPCK from the pulse generator 101. The latches of the logic circuit 200 operate synchronously with the pulse signal GPCK provided by pulse generator 101.

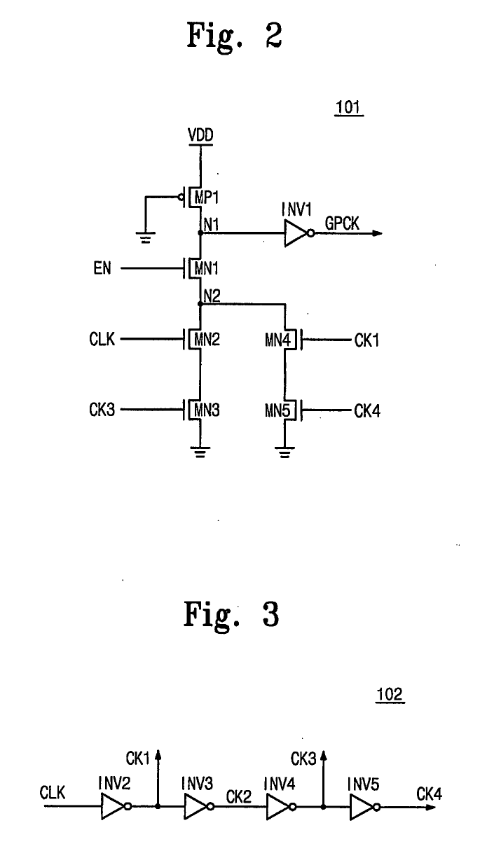

FIG. 2 is a circuit diagram further illustrating the pulse generator 101 of FIG. 1. Referring to FIG. 2, one embodiment of pulse generator 101 includes a PMOS transistor MP1, NMOS transistors MN1˜MN5, and an inverter INV1.

The source of the PMOS transistor MP1 is connected to an operation voltage (or power source voltage) VDD. The gate of the PMOS transistor MP1 is coupled to ground voltage GND, and the drain of the PMOS transistor MP1 is connected to the drain of the NMOS transistor MN1 and an input node of the inverter INV1 through a first node N1.

The gate of the NMOS transistor MN1 receives the control signal EN and the source of the NMOS transistor MN1 is commonly connected to the drains of NMOS transistors MN2 and MN4 through a second node N2.

The gate of the NMOS transistor MN2 receives the clock signal CLK and the source of the NMOS transistor MN2 is connected to the drain of the NMOS transistor MN3.

The gate of the NMOS transistor MN4 receives the first delay clock signal CK1. The source of the NMOS transistor MN2 is connected to the drain of the NMOS transistor MN5. The gate of the NMOS transistor MN3 receives the third delay clock signal CK3. The source of the NMOS transistor MN3 is connected to ground voltage GND. The gate of the NMOS transistor MN5 receives the fourth delay clock signal CK4 and the source of the NMOS transistor MN5 is connected to ground voltage GND.

In the illustrated embodiment, the pulse generator 101 receives the control signal EN and the clock signal CLK, and generates the pulse signal GPCK on the rising and falling edges of the clock signal CLK during an active period defined by the control signal EN. The pulse generator 101 transfers the pulse signal GPCK to the latches of logic circuit 200.

The latches of logic circuit 200 may be implemented as flip-flops that synchronously operate in relation to the pulse signal GPCK provided by pulse generator 101.

FIG. 3 is a circuit diagram further illustrating the delay clock generator of FIG. 1. Referring to FIG. 3, one embodiment of the delay clock generator 102 includes inverters INV2˜INV5.

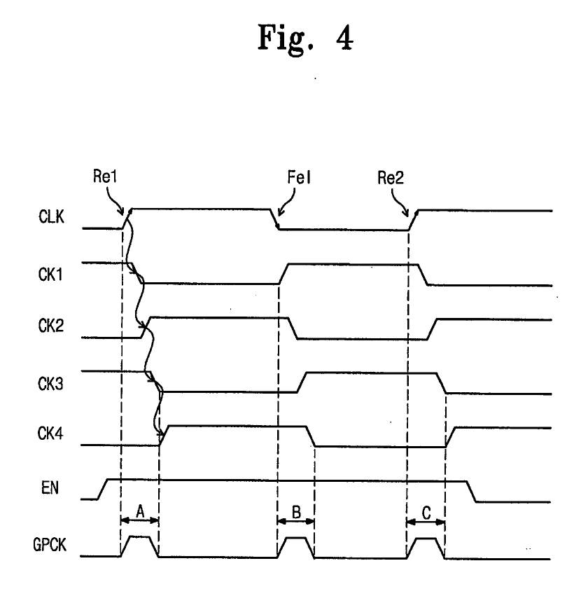

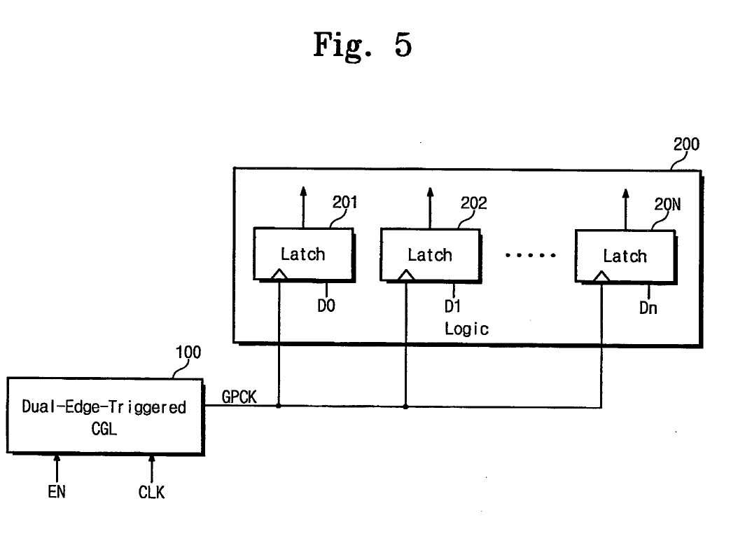

FIG. 4 is a related timing diagram for the dual-edge-triggered CGL circuit 100 shown in FIG. 1.

Referring collective to FIGS. 2 through 4, an exemplary operation of the pulse generator 101 and the delay clock generator 102 in the dual-edge-triggered CGL circuit 100 will be described.

Inverter (a first delay clock generator) INV2 of delay clock generator 102 receives and logically inverts the clock signal CLK, generating first delay clock signal CK1 from the inverted clock signal. First delay clock signal CK1 from delay clock generator 102 is provided to the gate of NMOS transistor MN4 of pulse generator 101.

Inverter (a second delay clock generator) INV3 of delay clock generator 102 receives and logically inverts the first delay clock signal CK1, generating the second delay clock signal CK2 from the inversed first delay clock signal. The second delay clock signal CK2 from delay clock generator 102 is not provided to the pulse generator 101.

Inverter (a third delay clock generator) INV4 of delay clock generator 102 receives and logically inverts the second delay clock signal CK2 generating the third delay clock signal CK3 from the inverted second delay clock signal. The third delay clock signal CK3 from delay clock generator 102 is provided to the gate of NMOS transistor MN3 of pulse generator 101.

Inverter (a fourth delay clock generator) INV5 of delay clock generator 102 receives and logically inverts the third delay clock signal CK3, generating the fourth delay clock signal CK4 from the inverted third delay clock signal. The fourth delay clock signal CK4 from delay clock generator 102 is provided to the gate of NMOS transistor MN5 of pulse generator 101.

Inverter INV2 operates to reduce delay as much as reasonably possible. Thus, the first delay clock signal CK1 from inverter INV2 has a small delay time at a rising or falling edge of the clock signal CLK, thereby quickly inverting the clock signal.

Pulse generator 101 receives the control signal EN, the clock signal CLK, and the first, third, and fourth delay clock signals CK1, CK2, CK3, and CK4.

The control signal EN applied to pulse generator 101 is also applied to the gate of NMOS transistor MN1 and the clock signal CLK is applied to the gate of NMOS transistor MN2. The third delay clock signal CK3 is applied to the gate of NMOS transistor MN3 and the first delay clock signal CK1 is applied to the gate of NMOS transistor MN4. The fourth delay clock signal CK4 is applied to the gate of NMOS transistor MN5.

The gate of PMOS transistor MP1 of pulse generator 101 is coupled to ground voltage GND, such that the PMOS transistor MP1 normally maintains an ON state.

During periods wherein the control signal EN is inactive, (i.e., when the control signal EN is low in the illustrated embodiment), NMOS transistor MN1 of pulse generator 101 is turned OFF by the control signal EN. Therefore, the voltage apparent at node N1 goes high by the operation voltage VDD regardless of the operation of NMOS transistors MN2˜MN5 controlled by first, third, and fourth delay clock signals CK1, CK3, and CK4. A logical high at first node N1 is inverted to a low for the pulse signal GPCK through the inverter INV1, and under these conditions a low GPCK is applied to logic circuit 200.

Referring to the timing diagram of FIG. 4, when the control signal EN is low, the pulse signal GPCK provided by pulse generator 101 is low regardless of the clock signal CLK, and the first, third, and fourth delay clock signals CK1, CK3, and CK4 generated by pulse generator 101.

Thus, pulse generator 101 generates and transfers a low pulse signal GPCK to logic circuit 200 when the control signal EN is low without generating a pulsed (low-to-high transitioning) signal in response to the clock signal CLK, and the first, third, and fourth delay clock signals CK1, CK3, and CK4. Thus, when the control signal EN is inactive, the pulse signal GPCK provided by pulse generator 101 is maintained at a low level without latch triggering pulse waveform(s). As a result, the latches of logic circuit 200 retain any previously applied data without change.

However, during active periods for the control signal EN, (i.e., periods in the illustrated example when the control signal EN is high), NMOS transistor MN1 of pulse generator 101 is turned ON by the control signal EN. As PMOS transistor MP1 is always turned ON by ground voltage GND, a current developed by application of the operation voltage VDD flows toward the second node N2 by way of PMOS transistor MP1 and NMOS transistor MN1.

If the clock signal CLK goes high at the rising edge Re1 of the clock signal CLK, NMOS transistor MN2 of pulse generator 101 is turned ON when the clock signal CLK goes high.

Referring to the timing diagram of FIG. 4 for the first through fourth delay clock signals CK1˜CK4 generated by delay clock generator 102, the first delay clock signal CK1 is generated from the inverter INV2 of delay clock generator 102 which receives the clock signal CLK, such that it goes low after a predetermined delay time when the clock signal CLK goes high at the rising edge Re1. The second delay clock signal CK2 is generated from the inverter INV3 of delay clock generator 102 which receives the first clock signal CK1, such that it goes high after a predetermined delay time when the first delay clock signal CK1 goes low. Also, as the third delay clock signal CK3 goes low after a predetermined delay time by the inverter INV4 when the second delay clock signal CK2 goes high. The fourth delay clock signal CK4 goes high after a predetermined delay time by the inverter INV5 when the third delay clock signal CK3 goes low.

As illustrated in FIG. 4, on the rising edge Re1 of the clock signal CLK, the first delay clock signal CK1 high; the second delay clock signal CK2 is low; the third delay clock signal CK3 is high; and the fourth delay clock signal CK4 is low.

As the first delay clock signal CK1 is high at the rising edge Re1 of the clock signal CLK, NMOS transistor MN4 controlled by the first delay clock signal CK1 is turned ON. As the fourth delay clock signal CK4 is low, NMOS transistor MN5 controlled by the fourth delay clock signal CK4 is turned OFF.

Thus, the PMOS transistor MP1 of pulse generator 101 maintains its ON state by ground voltage GND and when the control signal EN is high, NMOS transistor MN1 is turned ON. As the clock signal CLK, the third delay clock signal CK3, and the first delay clock signal CK1 are high and the fourth delay clock signal CK4 is low, at the rising edge Re1 of the clock signal CLK, the corresponding NMOS transistors MN2˜MN4 are turned ON by the clock signal CLK, the third delay clock signal CK3, and the first delay clock signal CK1 and the NMOS transistor MN5 is turned OFF by the fourth delay clock signal CK4.

Therefore, current flows to the second node N2 by way of the PMOS transistor MP1 and NMOS transistor MN1. The current apparent at node N2 flows toward the ground terminal GND through the conductive NMOS transistors MN2 and MN3, but not through the NMOS transistors MN4 and MN5, because the NMOS transistor MN4 is turned ON while the NMOS transistor MN5 is turned OFF.

As current flows to the ground voltage terminal GND by way of PMOS transistor MP1 and NMOS transistors MN1˜MN3, a voltage apparent at first node N1 goes low. The low voltage at first node N1 is inverted to high through inverter INV1. Thus, pulse generator 101 outputs the pulse signal GPCK at a high level.

Continued with the timing diagram of FIG. 4, when the clock signal CLK high, and after a predetermined delay time from the rising edge Re1 of the clock signal CLK, the first delay clock signal CK1 goes low, the second delay clock signal CK2 is low, the third delay clock signal CK3 is high, and the fourth delay clock signal CK4 is low. NMOS transistor MN4 is turned OFF by the low first delay clock signal CK1 and NMOS transistor MN5 is turned OFF by the low fourth delay clock signal CK4. Otherwise, as the clock signal CLK and the third delay clock signal CK3 are high, NMOS transistors MN2 and MN3 are turned ON to force the voltage apparent at first node N1 to low. This low voltage at the first node N1 is inverted to high through inverter INV1. Thus, pulse generator 101 outputs the pulse signal GPCK at a high level.

When the clock signal CLK is high and the second delay clock signal CK2 goes high, NMOS transistors MN4 and MN5 are turned OFF because the first and fourth delay clock signal CK1 and CK4 are low. Transistors MN2 and MN3 are turned ON because the clock signal CLK and the third delay clock signal CK3 are high. As the NMOS transistors MN2 and MN3 are turned ON while the NMOS transistors MN4 and MN5 are turned OFF, a voltage apparent at the first node N1 goes low as described above. This low voltage at the first node N1 is inverted to high through inverter INV1. Thus, pulse generator 101 outputs the pulse signal GPCK at a high level.

When the clock signal CLK is high and the third delay clock signal CK3 goes low, NMOS transistors MN4 and MN5 are turned OFF because the first and fourth delay clock signal CK1 and CK4 are low. Transistor MN2 is turned ON because the clock signal CLK is high. NMOS transistor MN3 is turned OFF because the third delay clock signal CK3 goes low. As NMOS transistors MN3, MN4, and MN5 are turned OFF, the voltage apparent of the first node N1 goes high in response to voltage VDD. This high level voltage at first node N1 is inverted to low through inverter INV1. Thus, pulse generator 101 outputs the pulse signal GPCK at a low level.

When the clock signal CLK is high and the fourth delay clock signal CK4 goes high, the delay clock signals CK1 and CK3 are low. NMOS transistors MN2 and MN5 are turned ON because the fourth delay clock signal CK4 and the clock signal CLK are high. But, NMOS transistors MN3 and MN4 are turned OFF because the first and third delay clock signals CK1 and CK3 are low. As NMOS transistors MN3 and MN4 are turned OFF, a voltage apparent at the first node N1 goes high in response to voltage VDD. This high level voltage apparent at the first node N1 is inverted to low through inverter INV1. Thus, pulse generator 101 outputs the pulse signal GPCK at a low level.

As a result of the foregoing, pulse generator 101 outputs a high level signal through ON NMOS transistors MN2 and MN3 at the rising edge Re1 of the clock signal CLK. The high signal is converted to a low at the time when the third delay clock signal CK3 goes low. That is, pulse generator 101 outputs a single pulse “A” at the rising edge Re1 of the clock signal CLK. Referring again to the timing diagram of FIG. 4, the rising edge pulse signal “A” provided by pulse generator 101 goes high at the rising edge Re1 of the clock signal CLK and goes low at the time when the third delay clock signal CK3 goes low. Thus, the pulse width for the rising edge pulse signal “A” generated at the rising edge Re1 is determined by the total delay time of the clock signal CLK through inverters INV2˜INV4.

Another pulse signal “C” generated at a rising edge Re2 of the clock signal CLK arises from the same operation and so will not be described in repetitive detail.

NMOS transistor MN1 is turned ON when the control signal EN is high. As PMOS transistor MP1 is always turned ON, a current flows to second node N2 in response to voltage VDD through PMOS transistor MP1 and NMOS transistor MN1.

When the clock signal CLK goes low at a falling edge Fe1, NMOS transistor MN2 of pulse generator 101 is turned OFF as the clock signal CLK is low.

Referring to the timing diagram of FIG. 4 for the first through fourth delay clock signals CK1˜CK4 provided by delay clock generator 102, the first delay clock signal CK1 is generated from inverter INV2 of delay clock generator 102 which receives the clock signal CLK, such that it goes high after a predetermined delay time when the clock signal CLK goes low at the falling edge Fe1. The second delay clock signal CK2 is generated from inverter INV3 of delay clock generator 102, which receives the first clock signal CK1, such that it goes low after a predetermined delay time when the first delay clock signal CK1 goes high. The third delay clock signal CK3 goes high after a predetermined delay time by operation of inverter INV4 when the second delay clock signal CK2 goes low. The fourth delay clock signal CK4 goes low after a predetermined delay time by operation of inverter INV5 when the third delay clock signal CK3 goes high.

As illustrated in the timing diagram shown in FIG. 4, on the falling edge Fe1 of the clock signal CLK, the first delay clock signal CK1 is low, the second delay clock signal CK2 is high, the third delay clock signal CK3 is low, and the fourth delay clock signal CK4 is high.

As the first delay clock signal CK1 is low at the falling edge Fe1 of the clock signal CLK, NMOS transistor MN4 controlled by the first delay clock signal CK1 is turned OFF. As the fourth delay clock signal CK4 is high, NMOS transistor MN5 controlled by the fourth delay clock signal CK4 is turned ON.

As the third delay clock signal CK3 is low at the falling edge Fe1 of the clock signal CLK, NMOS transistor MN3 controlled by the third delay clock signal CK3 is turned OFF.

As the NMOS transistors MN2, MN3, and MN4 are turned OFF while NMOS transistor MN5 is turned ON, a voltage apparent at first node N1 goes high in response to voltage VDD. The high voltage apparent at the first node N1 is inverted to low through inverter INV1. Thus, pulse generator 101 outputs the pulse signal GPCK at a low level.

Continued with the timing diagram shown in FIG. 4, when the clock signal CLK is low, and after a predetermined delay time from the falling edge Fe1 of the clock signal CLK, the first delay clock signal CK1 goes high.

If the first delay clock signal CK1 goes high, the second delay clock signal CK2 is high, the third delay clock signal CK3 is low, and the fourth delay clock signal CK4 is high. NMOS transistor MN4 is turned ON by the high first delay clock signal CK1 and NMOS transistor MN5 is turned ON by the high fourth delay clock signal CK4. Otherwise, as the clock signal CLK and the third delay clock signal CK3 are low, NMOS transistors MN2 and MN3 are turned OFF.

Therefore, current flows to the second node N2 in response to voltage VDD by way of PMOS transistor MP1 and NMOS transistor MN1. The current apparent at the second node N2 flows toward the ground voltage terminal GND through conductive NMOS transistors MN4 and MN5, but not through NMOS transistors MN2 and MN3, because NMOS transistors MN2 and MN3 are turned OFF while NMOS transistors MN4 and MN5 are turned ON.

As current flows to the ground voltage terminal GND by way of PMOS transistor MP1 and NMOS transistors MN1, MN4, and MN5, the voltage apparent at the first node N1 goes low. The low voltage apparent at the first node N1 is inverted to high through inverter INV1. Thus, pulse generator 101 outputs the pulse signal GPCK at a high level.

When the clock signal CLK is low and the second delay clock signal CK2 goes low, NMOS transistors MN4 and MN5 are turned ON because the first and fourth delay clock signal CK1 and CK4 are high. But, transistors MN2 and MN3 are turned OFF because the clock signal CLK and the third delay clock signal CK3 are low. As NMOS transistors MN2 and MN3 are turned OFF while NMOS transistors MN4 and MN5 are turned ON, the voltage apparent at the first node N1 goes low as described above. This low voltage apparent at the first node N1 is inverted to high through inverter INV1. Thus, pulse generator 101 outputs the pulse signal GPCK at a high level.

When the clock signal CLK is low and the third delay clock signal CK3 goes high, NMOS transistors MN4 and MN5 are turned ON because the first and fourth delay clock signal CK1 and CK4 are high. NMOS transistor MN2 is turned OFF because the clock signal CLK is low. NMOS transistor MN3 is turned ON because the third delay clock signal CK3 goes high. As NMOS transistors MN4, and MN5 are turned ON while NMOS transistor MN2 is turned OFF, a voltage apparent at the first node N1 goes low in response to voltage VDD. This low voltage apparent at the first node N1 is inverted to high through inverter INV1. Thus, pulse generator 101 outputs the pulse signal GPCK at a high level.

When the clock signal CLK is low and the fourth delay clock signal CK4 goes low, the first delay clock signal CK1 is high while the third delay clock signal CK3 is also high. NMOS transistors MN2 and MN5 are turned OFF because the fourth delay clock signal CK4 and the clock signal CLK are low. But, NMOS transistors MN3 and MN4 are turned ON because the first and third delay clock signals CK1 and CK3 are high. As NMOS transistors MN2 and MN5 are turned ON, the voltage apparent at the first node N1 goes high in response to voltage VDD. This high voltage apparent at the first node N1 is inverted to low through inverter INV1. Thus, pulse generator 101 outputs the pulse signal GPCK at a low level.

As a result, pulse generator 101 outputs a high level signal through ON NMOS transistors MN4 and MN5 at the rising edge of the first delay clock signal CK1 inverted with a predetermined delay time from the falling edge Fe1 of the clock signal CLK. The high is converted to a low at the time when the fourth delay clock signal CK4 goes low. That is, pulse generator 101 outputs a single pulse signal “B” at a rising edge of the first delay clock signal CK1 inverted with a predetermined delay time from the falling edge Fe1 of the clock signal CLK.

Referring to the timing diagram of FIG. 4, the falling edge pulse signal B goes high on the rising edge of the first delay clock signal CK1 and goes low when the fourth delay clock signal CK4 goes low. Thus, the pulse period for the falling edge pulse signal “B” output by pulse generator 101 is determined by the total delay time of the clock signal CLK through inverters INV3˜INV5.

Since inverter INV2 is designed to have as little delay as is possible, the first delay clock signal CLK generated through inverter INV2 has a short delay time at the rising or falling edge of the clock signal CLK and may be correspondingly inverted very quickly. As short as the delay time provided by inverter INV2 is, the first delay clock signal CK1 is more quickly inverted at the rising or falling edge of the clock signal CLK and the falling edge pulse signal “B” output by pulse generator 101 is more near to the falling edge Fe1 of the clock signal CLK. Therefore, as short as the delay time provided by inverter INV2 is, the falling edge pulse signal “B” provided by pulse generator 101 is generated at the falling edge Fe1 of the clock signal CLK.

If the delay time provided by inverter INV2 becomes longer, (i.e., if the first delay clock signal CK1 is inverted to low from high around the middle of the high level period of the clock signal CLK from the rising edge Re1 of the clock signal CLK), the second through fourth delay clock signals CK2˜CK4 may also be delayed and inverted after the middle of the high level period of the clock signal CLK. Pulse generator 101 outputs the rising edge pulse signal “A” at a time when the third delay clock signal CK3 goes low. As the delay provided by inverter INV2 is lengthened, the transition time of the third delay clock signal CK3 becomes longer from the rising edge Re1 of the clock signal CLK. Thus, the rising edge pulse signal “A” proved by pulse generator 101 becomes longer in its active period.

As the first delay clock signal CK1 is inverted to low from high level around the middle of the high level period of the clock signal CLK from the rising edge Re1 of the clock signal CLK, the first delay clock signal CK1 is inverted to high level from low level around the middle of the low level period of the clock signal CLK from the falling edge Fe1 of the clock signal CLK. According to this, the second through fourth delay clock signals CK1˜CK4 are also delayed and inverted after the middle of the low level period of the clock signal CLK.

Thus, pulse generator 101 outputs the pulse signal B, after the falling edge Fe1 of the clock signal CLK, from when the first delay clock signal CK1 goes high to when the fourth delay clock signal CK4 goes low. Since the first delay clock signal CK1 goes high around the middle of the low level period, due to the longer delay provided by inverter INV2, after the falling edge Fe1 of the clock signal CLK, the point of generating the falling edge pulse signal “B” is around the middle of the low level period after the falling edge of the clock signal CLK.

If the delay period for inverter INV2 is lengthened, the falling edge pulse signal “B” provided by pulse generator 101 is not generated at the falling edge Fe1 of the clock signal CLK. Thus, as described above, inverter INV2 may be designed such that its delay time is as short as possible in relation to generating the falling edge pulse signal “B”.

Considering that the period of the rising edge pulse signal “A” generated is same as the period of falling edge pulse signal “B”, the total delay time provided by inverters INV2˜INV4 will be identical to the total delay time provided by inverters INV3˜INV5. For this reason, inverters INV2˜INV5 may be designed to make the total delay provide by inverters INV2˜INV4 the same as the total delay time provided by inverters INV3˜INV5.

FIG. 5 is a block diagram illustrated a general logic circuit 200 synchronized by operation of a dual-edge-triggered CGL circuit in accordance with an embodiment of the invention.

Referring to FIG. 5, logic circuit 200 includes a plurality of latches 201, 202, . . . , 20N (201˜20N).

Pulse generator 101 of Dual-edge-triggered CGL circuit 100 receives the first, third, and fourth delay clock signals CK1, CK3, and CK4, and the control signal EN, and generates the pulse signal GPCK at the rising and falling edges of the clock signal CLK in response to the clock signal CLK and the first, third, and fourth delay clock signals CK1, CK3, and CK4. The pulse signal GPCK is applied to latches 201˜20N of logic circuit 200. The latches 201-20N of logic circuit 200 function as flip-flops synchronously with the pulse signal GPCK on the rising and falling edges of the clock signal CLK.

Each latch 201-20N may be implemented using a flip-flop circuit operating synchronously with the pulse signal GPCK to implement logic circuit 200 having a multiple data bit (D0-Dn) latching capability. Thus, the flip-flop circuit synchronized with the pulse signal GPCK of the dual-edge-triggered CGL circuit 100 uses a smaller number of latch circuits than the conventional master-slave flip-flop circuit. Meantime, each pulse-based flip-flop of a logic circuit includes a pulse generator and a latch, but the dual-edge-triggered CGL circuit 100 shown in FIG. 5 directly generates the pulse signal without a need of the pulse generator to each flip-flop like the pulse-based flip-flop. That is, the flip-flop synchronized with the pulse signal of the dual-edge-triggered CGL circuit 100 is formed of a single latch.

As a result, since the dual-edge-triggered CGL circuit 100 operates to gate the clock signal at the rising and falling edges, it reduces power consumption caused by clock switching. Moreover, a storage unit, i.e., the flip-flop, connected to the output of dual-edge-triggered CGL circuit 100 may be formed as a single latch circuit capable of operating at high frequency but with relatively low power consumption.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A dual-edge-triggered clock-gated logic circuit comprising:
a delay clock generator operating to generate first, second, third and fourth delay clock signals in response to a clock signal; and
a pulse generator operating to generate a pulse signal in response to the clock signal, the first, the third, and the fourth delay clock signals, and the control signal,
wherein the pulse generator operates to generate the pulse signal at the rising and falling edges of the clock signal.

2. The logic circuit of claim 1, wherein the pulse generator operates to generate the pulse signal during an active period defined by the control signal.

3. The logic circuit of claim 1, wherein the pulse signal at the rising edge of the clock signal is defined in relation to the rising edge of the clock signal and the falling edge of the third edge of the third delay clock signal.

4. The logic circuit of claim 1, wherein the pulse signal at the falling edge of the clock signal is defined in relation to the rising edge of the first delay clock signal and the falling edge of the fourth delay clock signal.

5. The logic circuit of claim 1, wherein the delay clock generator comprises:
first, second, third, and fourth delay clock generators operating to respectively generate the first delay clock signal, the second delay clock signal, the third delay clock signal, and the fourth delay clock signal.

6. The logic circuit of claim 5, wherein the first delay clock generator receives and inverts the clock signal and generates the first delay clock signal by delaying for a first delay period the inverted clock signal.

7. The logic circuit of claim 5, wherein the second delay clock generator receives and inverts the first delay clock signal and generates the second delay clock signal by delaying for a second delay period the inverted first delay clock signal.

8. The logic circuit of claim 5, wherein the third delay clock generator receives and inverts the second delay clock signal and generates the third delay clock signal by delaying for a third delay period the inverted second delay clock signal.

9. The logic circuit of claim 5, wherein the fourth delay clock generator receives and inverts the third delay clock signal and generates the fourth delay clock signal by delaying for a fourth delay period the inverted third delay clock signal.

10. The logic circuit of claim 5, wherein the first delay period is as short as possible.

11. The logic circuit of claim 5, wherein a first total delay time equal to the sum of the first, second and third delay periods is the same as a second total delay equal to the sum of the second, third and fourth delay periods.

12. The logic circuit of claim 1, wherein the pulse generator comprises:
a first transistor connected between a power source voltage and a first node and operating in response to a ground voltage;
a second transistor connected between the first node and a second node and operating in response to the control signal;
third and fourth transistors serially connected between the second node and the ground voltage and operating in response to the clock signal and the third delay clock signal;
fifth and sixth transistors serially connected between the second node and the ground voltage and operating in response to the first delay clock signal and the fourth delay clock signal; and
an inverter outputting the pulse signal in response to a voltage apparent at the first node.

13. A low power logic circuit comprising:
a dual-edge-triggered clock-gated logic circuit generating a pulse signal at the rising and falling edges of a clock signal; and
a logic circuit operating synchronously with the pulse signal,
wherein the logic circuit includes a plurality of latches driven by the pulse signal.

14. The low power logic circuit of claim 13, wherein the dual-edge-triggered clock-gated logic circuit comprises:
a delay clock generator operating to generate first, second, third and fourth delay clock signals in response to a clock signal; and
a pulse generator operating to generate a pulse signal in response to the clock signal, the first, the third, and the fourth delay clock signals, and the control signal,
wherein the pulse generator operates to generate the pulse signal at the rising and falling edges of the clock signal.

15. The low power logic circuit of claim 14, wherein the pulse generator operates to generate the pulse signal during an active period defined by the control signal.

16. The low power logic circuit of claim 14, wherein the pulse signal at the rising edge of the clock signal is defined in relation to the rising edge of the clock signal and the falling edge of the third edge of the third delay clock signal.

17. The low power logic circuit of claim 14, wherein the pulse signal at the falling edge of the clock signal is defined in relation to the rising edge of the first delay clock signal and the falling edge of the fourth delay clock signal.

18. The low power logic circuit of claim 14, wherein the delay clock generator comprises:
first, second, third, and fourth delay clock generators operating to respectively generate the first delay clock signal, the second delay clock signal, the third delay clock signal, and the fourth delay clock signal.

19. A method for operating a dual-edge-triggered clock-gated logic circuit, comprising:
generating a first delay clock signal by inverting and delaying a clock signal by a first delay period;
generating a second delay clock signal by inverting and delaying the first delay clock signal by a second delay period;
generating a third delay clock signal by inverting and delaying the second delay clock signal;
generating a fourth delay clock signal by inverting and delaying the third delay clock signal; and
generating a pulse signal in response to the clock signal, the first, third, and fourth delay clock signals, and a control signal,
wherein the pulse signal is generated at the rising and falling edges of the clock signal during an active period defined by the control signal.
